(19) United States
(12) Patent Application Publication
(10) Pub. No.: US 2026/0231592 A1
(43) Pub. Date: Aug. 6, 2026

(54) UV LIGHT DETECTOR

(71) Applicant: THE BOARD OF REGENTS FOR THE OKLAHOMA AGRICULTURAL AND MECHANICAL COLLEGES, Stillwater, OK (US)

(72) Inventor: Do Young KIM, Tulsa, OK (US)

(73) Assignee: THE BOARD OF REGENTS FOR THE OKLAHOMA AGRICULTURAL AND MECHANICAL COLLEGES, Stillwater, OK (US)

(21) Appl. No.: 19/159,869

(22) PCT Filed: Feb. 15, 2024
(86) PCT No.: PCT/US2024/015936

§ 371 Date: Aug. 26, 2025

Related U.S. Application Data
(60) Provisional application No. 63/448,549, filed on Feb. 27, 2023.

(51) Int. Cl. H10K 30/40; H10F 30/22; H10F 77/30; H10K 30/60; H10K 85/50

(52) U.S. Cl. CPC H10K 30/40; H10F 30/22; H10F 77/331; H10K 30/60; H10K 85/50

(57) ABSTRACT

Ultraviolet-light photodetector structures, and methods relating to the structure, where the structure includes a silicon-photoelectric conversion element and a UV-to-visible down conversion layer. The UV-to-visible down conversion layer has a halide-perovskite component. The halide-perovskite component has an absorption spectrum at wavelengths in the range of 400 nm or less and has an associate photoluminescence (PL) emission resulting in an emission spectrum with wavelengths in the range of above 400 nm. The UV-to-visible down conversion layer is associated with the silicon-photoelectric conversion element such that light in the absorption spectrum incident on the UV-to-visible down conversion layer results in a visible light emission which is incident on the silicon-photoelectric conversion element so as to produce an electrical signal.

### CROSS REFERENCE TO RELATED APPLICATIONS

The present application claims priority to U.S. Provisional Application No. 63/448,549 filed on Feb. 27, 2023, which is incorporated herein.

### FIELD

The present invention relates generally to light detectors, more specifically to the detection of ultraviolet light.

### BACKGROUND

Ultra-violet (UV) photodetectors have broad applications in many areas such as scintillator light detection, time correlated photo detection, ultra-fast fluorescent microscopy detection, and ultra-dense spatial imaging. Silicon-based photodiodes have been commercialized with a variety of applications even including single-photon avalanche photodiodes (SPADs) which offer low dark count rates, high detection efficiencies and high-count rates in the visible to near-infrared range. The disadvantage of using Si diodes in the UV wavelength range is that the sensitivity or responsiveness maximum is in the wavelength range of 600 to 800 nm. (The terms sensitivity and responsiveness are used synonymously.) The sensitivity of the Si diodes is lower in the UV range (400 nm or less) than in the visible and infrared wavelength range (above 400 nm).

This sensitivity issue for Si diodes can be the result of the penetration depth of the light. Sensors made of silicon have the disadvantage that UV light has a penetration depth of typically only a few nanometers, while the long-wave components (visible and infrared light) have a greater penetration depth into the silicon. In other words, absorption occurs before the UV photon reaches the detection region in the Si-based photodetectors, where penetrating photons produce a charge carrier generation and/or a charge carrier depletion at the pn transition, which are usually located deep in the bulk material and far from the site entry of the radiation to be detected. Thus, visible and infrared photons reach the detection region and UV photons do not, thus distorting the measured values. As a result, traditional Si-based photodetector show poor performance in UV regions.

Accordingly, it would be advantageous to develop Si-based photodetectors that can accurately detect UV light.

### BRIEF DESCRIPTION OF THE DRAWINGS

The drawings included in this disclosure illustrate certain aspects of the embodiments described herein. However, the drawings should not be viewed as exclusive embodiments. The subject matter disclosed herein is capable of considerable modifications, alterations, combinations, and equivalents in form and function, as well being evident to those skilled in the art with the benefit of this disclosure. Additionally, the drawings are not to scale.

FIG. 1 is schematic illustration of an ultraviolet-light photodetector structure in accordance with this disclosure.

FIG. 2 is a schematic illustration of an example of silicon diode detector useful in the structure of this disclosure, FIG. 3 is a graph illustrating the photoluminescence excitation and photoluminescence spectra of CsCuzI3 and the associated Stokes shift.

FIG. 4 is an appropriate energy band diagram for a lead-free inorganic metal halide perovskite (CsCuzI3) in relation to three different organic-host components FIG. 5 is a graph illustrating photoluminescence quantum yield (PLQY) in relation to a layer with no organic-host component and layers having one of three organic-host components.

FIG. 6 is a schematic illustration of an ultraviolet-light photodetector structure used in Example 2.

FIG. 7 is a graph illustrating the detection of ultraviolet light by the photodetector structure of Example 2.

### DETAILED DESCRIPTION

The present disclosure may be understood more readily by reference to this detailed description as well as to the examples included herein. In addition, numerous specific details are set forth in order to provide a thorough understanding of the embodiments and examples described herein. However, those of ordinary skill in the art will understand the embodiments and examples described herein can be practiced without these specific details. In other instances, methods, procedures and components have not been described in detail so as not to obscure the related relevant feature being described. Also, the description is not to be considered as limiting the scope of the embodiments described herein.

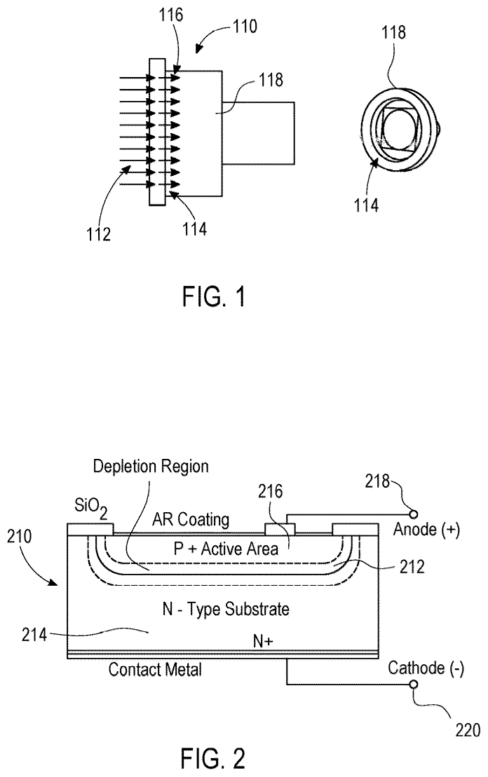

This disclosure describes an innovative silicon-based (Si-based) ultraviolet (UV) light photodetector structure using an efficient UV-to-visible down-conversion layer, or photo-conversion layer. With reference to FIG. 1, the described Si-based UV photodetector structure 110 is capable of absorbing light in the UV spectrum 112 in a photo-conversion layer 114, which will convert the absorbed UV light to visible lights 116. Then the down-converted visible light 116 will be absorbed by an Si-based photodetector 118. Generally, Si-based photodetectors 118 will have very low light sensitivity in UV light wavelengths. However, in the Si-based UV photodetector structure of this disclosure, there is no surface recombination issue causing insufficient carrier collection. Therefore, the UV detector of this disclosure makes a compact, low-cost, high-resolution, low-noise, high-efficiency UV photodetectors and sensors do whatever Si-based visible-light photodetectors and sensors can do. As used herein, “photodetector” will refer to both photodetectors and sensors, as well as other light detection apparatuses.

The silicone-based photodetector is a silicon-photoelectric conversion element such as a Si-based photodiode as are known in the art. A photodiode is a semiconductor device with a P-N junction that converts photons (or light) into electrical current. The P layer has an abundance of holes (positive), and the N layer has an abundance of electrons (negative). Photodiodes can be manufactured from a variety of materials including, but not limited to, silicon, germanium, and indium gallium arsenide. Each material uses different properties for cost benefits, increased sensitivity, wavelength range, low noise levels, or even response speed.

In the current disclosure, silicon-based detectors or photodiodes are used. For example, FIG. 2 schematically illustrates a silicon photodiode. FIG. 2 shows a cross section of a typical photodiode 210. A depletion region 212 is formed from diffusion of electrons from the N layer 214 to the P layer 216 and the diffusion of holes from the P layer 216 to the N layer 214. This creates a region 212 between the two layers where no free carriers exist. This develops a built-in voltage to create an electric field across the depletion region 212. This allows for current to flow only in one direction (anode 218 to cathode 220).

A photon can strike an atom within the device and release an electron if the photon has enough energy. This creates an electron-hole pair (e− and h+) where a hole is simply an “empty space” for an electron. If photons are absorbed in either the P or N layers, the electron hole pairs can be recombined in the materials as heat if they are far enough away (at least one diffusion length) from the depletion region. Photons absorbed in the depletion region (or close to it) will create electron hole pairs that will move to opposite ends due to the electric field. Electrons will move toward the positive potential on the cathode, and the holes will move toward the negative potential on the anode. These moving charge carriers form the current (photocurrent) in the photodiode. When photons of energy greater than 1. leV (the bandgap of silicon) fall on the device, they are absorbed and electron-hole pairs are created. The depth at which the photons are absorbed depends upon their energy; the lower the energy of the photons, the deeper they are absorbed. As will be realized, UV light has a shorter wavelength and thus more energy than visible light and thus penetrates less into the Si-based detector.

Between the light source and the silicon-photoelectric conversion element is the UV-to-visible down conversion layer. While generally a layer deposited on the silicon-photoelectric conversion element is preferred, the term “layer” as used herein includes both deposited layers and UV-to-visible down conversion elements that are separate from the silicon-photoelectric conversion element, such as screens, filters and the like. When the UV-to-visible down conversion layer is a deposit layer it can be, for example, from about 1 μm to about 500 μm thick. However, the important aspects are that the UV-to-visible down conversion layer has an absorption spectrum and an emission spectrum, as described below, and is associated with the silicon-photelectric conversion element such that light in the absorption spectrum incident on the UV-to-visible down conversion layer results in a visible light emission which is incident on the silicon-photoelectric conversion element so as to produce an electrical signal.

The UV-to-visible down conversion layer has a halide-perovskite component, or halide semiconductor component. The halide-perovskite component can be an inorganic halide perovskite (inorganic halide semiconductor) or a hybrid organic-inorganic perovskite (hybrid organic-inorganic halide semiconductor) Typically, this will be a lead-free inorganic metal halide perovskite or a lead-free hybrid organic-inorganic metal halide perovskite (“lead-free hybrid perovskite”). The halide-perovskite component has an absorption spectrum at wavelengths in the range of 400 nm or less and has an associate photoluminescence (PL) emission resulting in an emission spectrum with wavelengths in the range of above 400 nm. For example, the absorption spectrum can be at wavelengths in the range of from 10 nm to 400 nm, or in the range of 100 nm to 400 nm. For example, the emission spectrum can be at wavelengths in the range of from above 400 nm to 1,100 nm, or in the range of from above 400 nm to 780 nm.

Generally, the halide-perovskite component can be selected from the group consisting of CsCu₂I₃, CsCu₂Cl₃, CsCu₂Br₃, CsCu₂Cl_{3-x-y}Br_{y}Iₓ, Cs₃Cu₂I₅, Cs₃Cu₂Br₅, Cs₃Cu₂Br₅₋ₓIₓ, (C₅H₇N₂)₂ZnBr₄, (C₅H₇N₂)₂HgBr₄, Rb₂CuBr₃, Rb₂CuCl₃, K₂CuCl₃, K₂CuBr₃, K₂CuI₃, K₂CuCl_{3-x-y}Br_{y}Iₓ, (TEP)₂Cu₂Br₄, (TEP)₂Cu₄Br₆, and mixtures thereof, wherein x is in the range of from 0 to 1, y is in the range of from 0 to 1, and TEP is tetraethylphosphonium (C₈H₂₀P). For example, the halide-perovskite component can be CsCu₂I₃.

Typically, these metal halides exhibit very large Stokes shifted broadband emissions due to self-trapped excitons (STEs)-based recombination mechanism. In this STEs-based emission, excited-state structural reorganization (deformation) occurs in these metal halides upon UV photo-excitations, which trap excitons and lead to strongly red-shifted broad photoemission spectra. For example, CsCu₂I₃ layer can be used because it has a very large stoke shift of 251 nm as shown in FIG. 3. The stoke shift means that CsCu₂I₃ has a significant difference between its absorption wavelengths and emission wavelengths. Therefore, the CsCu₂I₃ film shows strong UV light absorption (325 nm peak wavelength) and bright yellow emission (576 nm peak wavelength) as shown in FIG. 3.

Generally, the halide-perovskite component can be present in UV-to-visible down conversion layer in an amount from 0.1 wt % to 100 wt %, depending on the specifics of the use and detection required. In some embodiments, the halide-perovskite component will be present in UV-to-visible down conversion layer in an amount from 0.1 wt % to 99.9 wt %, with the remaining being a host material that will not interfere with the UV-to-visible down conversion aspect of the layer. For example, the host material can include, consist essentially, or consist of an organic-host component. Thus, the halide-perovskite component can be present in an amount from 0.1 wt % to 99.9 wt % and the organic-host component is present in an amount from 0.1 wt % to 99.9 wt %, based on the total amount of the UV-to-visible down conversion layer.

Suitable organic host materials are generally ones suitable for use as organic light-emitting diode (OLED) host materials. For example, the organic host material can be fluorescent and phosphorescent host materials for OLED as are known, such as one or more of 4,4′,4′-tris(carbazol-9-yl)triphenylamine (TCTA), NPB, 2,2′2″-(1,3,5-benzinetriyl)-tris(1-phenyl-1-H-benzimidazole) (TBPi), 1,3-Bis(N-carbazolyl)benzene (mCP), 4,4′-bis(carbazol-9-yl)biphenyl (CBP), 1,3-bis(triphenylsilyl)benzene (UGH), 9,9′-(5-(triphenylsilyl)-1,3-phenylene)bis(9H-carbazole) (SimCP), 2,6-bis(3-(9H-carbazol-9-yl)phenyl)pyridine (26DCzPPy), 9.9-spirobifluoren-2-yl-diphenyl-phosphine oxide (SPPO1), s 4,4′-Bis(2,2-diphenyl-ethen-1-yl)biphenyl (DPVBi), 4,4′-bis(9-ethyl-3-carbazovinylene)-1,1′-biphenyl(BCzVBi), N,N′-di-(1- naphthalenyl)-N,N-diphenyl-1,1′:4′,1″:4″,1″-quaterphenyl]-4.4″-diamine (4PNPD), p-bis p-N, N-diphenylaminostyryl benzene (DSA-Ph), BUBD-1, 2-methyl-9,10-di 2-naphthyl anthracene (MADN), Tris-(8-hydroxyquinoline)aluminum (Alq3), 4,7-Diphenyl-1,10-phenanthroline (Bphen), 2.9-dimethyl-47 diphenyl-1,10- phenanthroline (BCP), 3-(Biphenyl-4-yl)-5-(4-tert-butylphenyl)-4-phenyl-4H-1,2,4-triazole (TAZ), 1,3,5-Tri(m-pyrid-3-yl-phenyl)benzene (TmPyPB), bis-1,2-(3,5-di-3-pyridyl-phenyl)ben Zene (B3PyPB) or any combination thereof. In some embodiments, the organic-host is or includes a tri(m-pyridin-3-ylphenyl)benzene, such as 1,3,5-tris(3-pyridyl-3-phenyl)benzene (TmPyPB).

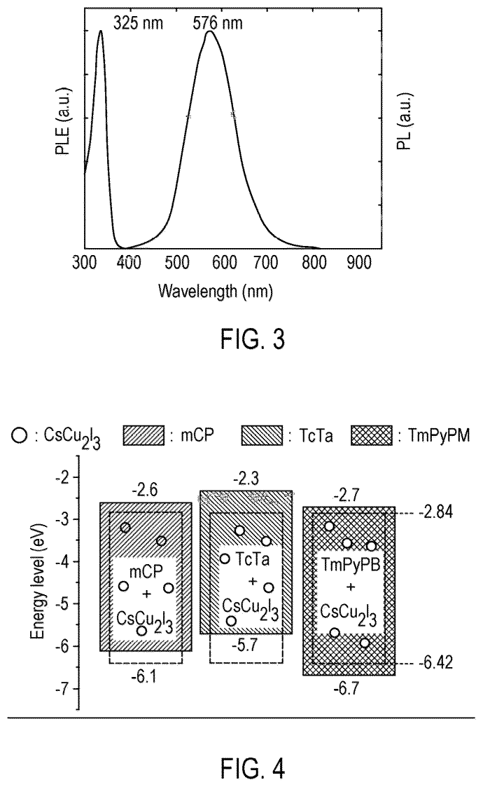

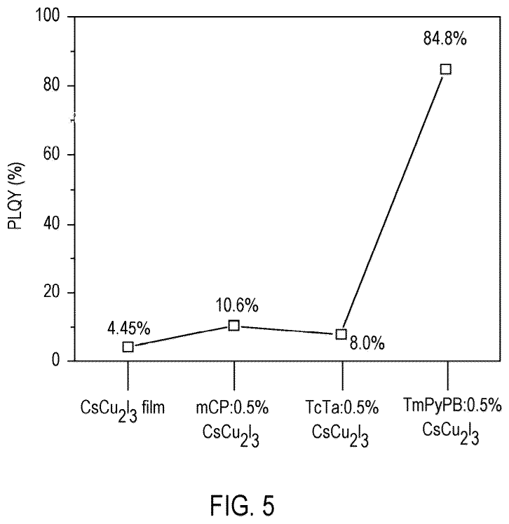

It has been discovered that in some uses it can be advantageous to select the organic-host component and the halide-perovskite component such that they have appropriate energy band alignment. As used herein appropriate energy band alignment refers to the conduction band minimum (CBM) of the halide-perovskite component being positioned below the lowest unoccupied molecular orbital (LUMO) level of the organic-host component molecules and at the same time the valence band maximum (VBM) of the halide-perovskite component has also to be positioned above the highest occupied molecular orbital (HOMO) level of organic-host component molecules. This can be further understood with reference to FIG. 4 where the principle is shown with respect to the halide-perovskite component being CsCu₂I₃ and the organic-host component being mCP, TcTa or TmPyPB, As can be seen, the CBM for CsCu₂I₃ is −2.84 eV and the CBM is below the LUMO for each of the three organic-host components. However, the VBM for CsCu₂I₃ is −6.42 eV and the VBM is only above the HOMO for TmPyPB. Thus, TmPyPB and CsCu₂I₃ have appropriate energy band alignment, but neither mCP nor TcTa have appropriate energy band alignment with CsCu₂I₃.

In some applications, a filter can be used in the ultraviolet-light photodetector structure so as to block all or a portion of visible light from reaching the UV-to-visible down conversion layer and transmitting all or a portion of UV light to the UV-to-visible down conversion layer. For example, the filter can block wavelengths of above 400 nm from reaching the photo-conversion layer and transmit all or at least a portion of light wavelengths at or below 400 nm to the UV-to-visible down conversion layer. Generally, in such applications the UV-to-visible down conversion layer can be positioned between the silicon-photoelectric conversion element and the filter layer.

In applications where the UV-to-visible down conversion layer is deposited directly on the silicon-photoelectric conversion element any suitable deposition process can be used. For example, the halide-perovskite component and an organic-host component can be deposited by vacuum thermal evaporation (VTE) film co-deposition process.

Thus, in accordance with some embodiments, the ultraviolet-light photodetector structure of this disclosure is produced by a method comprising:

The disclosure can be better understood with reference to the following examples.

### EXAMPLES

### Example 1

In order to better understand the effect of using an organic-host component with the halide-perovskite component, substrates were coated with a different photo conversion layers by vacuum thermal evaporation film co-deposition, The layers used were (a) CsCu₂I₃; (b) mCP with 0.5 wt-% CsCu₂I₃; (c) TcTa with 0.5 wt-% CsCu₂I₃; and (d) TmPyPB with 0.5 wt.-% CsCu₂I₃. Then each layered substrate was tested to determine the photoluminescence quantum yield (PLQY) of the yellow emission resulting from UV light exposure. The results can be seen in FIG. 5, which illustrate that use of an organic-host component results in increased PLQY; however, use of an organic-host component having energy alignment with the halide-perovskite component (TmPyPB with CsCu₂I₃) results in approximately a 20 times increase in the PLQY over the neat halide-perovskite component.

### Example 2

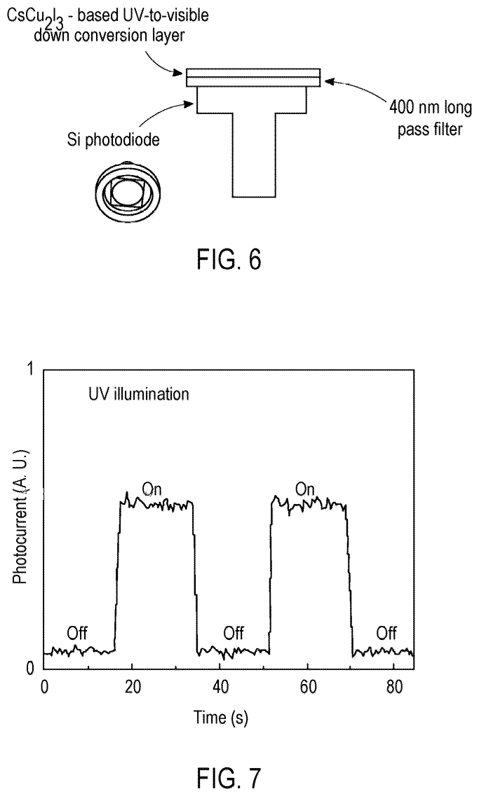

To test the effectiveness of a sensor in accordance with this disclosure, a 400 nm long pass filter was inserted between an Si-based photodiode and a CsCuzI3-based down-conversion layer, as shown in FIG. 6. The long pass filter had transmission spectrum excluding wavelengths shorter than 400 nm. This insured that no UV light directly reached the Si-based photodetector; therefore, the generation of the photocurrent in the Si-based photodiode under UV illumination would absolutely be due to the yellow emitted lights from the CsCuzI3-based down-conversion layer.

The CsCu₂I₃-based down-conversion layer was then exposed to a UV lamp with an output between about 290 nm and about 350 nm, with a peak at about 312 nm. The resulting photocurrent is illustrated in FIG. 7. As can be seen the test clearly show that the UV sensor in accordance with this disclosure worked to detect UV light.

Embodiments of the invention can be further understood by referenced to the following numbered embodiments.

Embodiment 1. An ultraviolet-light photodetector structure comprising:
a silicon-photoelectric conversion element;
a UV-to-visible down conversion layer having a halide-perovskite component that is a lead-free inorganic metal halide perovskite or a lead-free hybrid perovskite, wherein:
the halide-perovskite component has an absorption spectrum at wavelengths in the range of 400 nm or less and has an associate photoluminescence (PL) emission resulting in an emission spectrum with wavelengths in the range of above 400 nm, and
the UV-to-visible down conversion layer is associated with the silicon-photoelectric conversion element such that light in the absorption spectrum incident on the UV-to-visible down conversion layer results in a visible light emission which is incident on the silicon-photoelectric conversion element so as to produce an electrical signal.

Embodiment 2. The ultraviolet-light photodetector structure of Embodiment 1, further comprising a filter layer configured to block at least a portion light at wavelengths of above 400 nm from reaching the UV-to-visible down conversion layer and to transmit at least a portion of light wavelengths at or below 400 nm to the UV-to-visible down conversion layer, and wherein the UV-to-visible down conversion layer is positioned between the silicon-photoelectric conversion element and the filter layer.

Embodiment 3. A method for detecting UV light, the method comprising:
exposing a UV-to-visible down conversion layer to light so as to generate an emission having a wavelength in an emission spectrum, wherein the UV-to-visible down conversion layer has a halide-perovskite component that is a lead-free inorganic metal halide perovskite or a lead-free hybrid perovskite, and the halide-perovskite component has an absorption spectrum at wavelengths of 400 nm or less, the emission is a photoluminescence (PL) emission associated with the absorption spectrum, and the emission spectrum is at wavelengths of above 400 nm, and
exposing a silicon-photoelectric conversion element to the emission so as to produce an electrical signal representative of the amount of an exposure spectrum of ultraviolet light in the light, the exposure spectrum of ultraviolet light being at wavelengths of 400 nm or less.

Embodiment 4. The method of Embodiment 3, wherein the step of exposing a UV-to-visible down conversion layer to the light, further comprises:
filtering the light so as to reduce or remove light wavelengths above 400 nm; and
exposing the UV-to-visible down conversion layer to the filtered light.

Embodiment 5. A method for producing an ultraviolet-light photodetector structure, the method comprising:
providing a silicon-photoelectric conversion element;
depositing a halide-perovskite component and an organic host material onto the silicon-photoelectric conversion element by vacuum thermal evaporation film co-deposition to produce a UV-to-visible down conversion layer on the silicon-photoelectric conversion element, wherein the halide-perovskite component is a lead-free inorganic metal halide perovskite or a lead-free hybrid perovskite, and the halide-perovskite component has an absorption spectrum at a wavelengths in the range of 400 nm or less and has an associate photoluminescence (PL) emission resulting in an emission spectrum with wavelengths in the range of above 400 nm.

Embodiment 6. The method of Embodiment 5, wherein the UV-to-visible down conversion layer is associated with the silicon-photoelectric conversion element such that ultraviolet light in the absorption spectrum incident on the UV-to-visible down conversion layer results in a visible light emission which is incident on the silicon-photoelectric conversion element so as to produce an electrical signal.

Embodiment 7. The method of Embodiments 5 or 6, further comprising adding a filter layer, wherein the filter layer is configured to block at least a portion of light wavelengths above 400 nm from reaching the UV-to-visible down conversion layer and to transmit at least a portion of light wavelengths at or below 400 nm to the UV-to-visible down conversion layer, and wherein the UV-to-visible down conversion layer is positioned between the silicon-photoelectric conversion element and the filter layer.

Embodiment 8. The structure or method of any preceding Embodiment, wherein the absorption spectrum is at wavelengths in the range of from 10 nm to 400 nm and the emission spectrum is at wavelengths in the range of from above 400 nm to 1,100 nm.

Embodiment 9. The structure or method of any of Embodiments 1 to 7, wherein the absorption spectrum is at wavelengths in the range of from 100 nm to 400 nm and the emission spectrum is at wavelengths in the range of from above 400 nm to 780 nm.

Embodiment 10. The structure or method of any preceding Embodiment, wherein the halide-perovskite component is present in UV-to-visible down conversion layer in an amount from 0.1 wt % to 100 wt %.

Embodiment 11. The structure or method of any preceding Embodiment, wherein the UV-to-visible down conversion layer is from about 1 μm to about 500 μm thick.

Embodiment 12. The structure or method of any preceding Embodiment, wherein the halide-perovskite component is selected from the group consisting of CsCu₂I₃, CsCu₂Cl₃, CsCu₂Br₃, CsCu₂Cl_{3-x-y}Br_{y}Iₓ, Cs₃Cu₂I₅, Cs₃Cu₂Br₅, Cs₃Cu₂Br₅₋ₓIₓ, (C₅H₇N₂)₂ZnBr₄, (C₅H₇N₂) ₂HgBr₄, Rb₂CuBr₃, Rb₂CuCl₃, K₂CuCl₃, K₂CuBr₃, K₂CuI₃, K₂CuCl_{3-x-y}Br_{y}Iₓ, (TEP)₂Cu₂Br₄, (TEP)₂Cu₄Br₆, and mixtures thereof, wherein x is in the range of from 0 to 1, y is in the range of from 0 to 1, and TEP is tetraethylphosphonium (C₈H₂₀P).

Embodiment 13. The structure or method of any preceding Embodiment, wherein the UV-to-visible down conversion layer comprises the halide-perovskite component and an organic-host component.

Embodiment 14. The structure or method of Embodiment 13, wherein the organic-host component and the halide-perovskite component have appropriate energy band alignment.

Embodiment 15. The structure or method of Embodiments 13 or 14, wherein the organic-host is 1,3,5-tris(3-pyridyl-3-phenyl)benzene (TmPyPB).

Embodiment 16. The structure or method of any of Embodiments 13 to 15, wherein the halide-perovskite component is present in an amount from 0.1 wt % to 99.9 wt % and the organic-host component is present in an amount from 0.1 wt % to 99,9 wt %, based on the total amount of the UV-to-visible down conversion layer.

Therefore, the present structures, systems and methods are well adapted to attain the ends and advantages mentioned, as well as those inherent therein. The particular examples disclosed above are illustrative only, as the structures, systems and methods may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative examples disclosed above may be altered or modified, and all such variations are considered within the scope and spirit of the present treatment additives and methods. While compositions and methods are described in terms of “comprising,” “containing,” “having,” or “including” various components or steps, the compositions and methods can also, in some examples, “consist essentially of” or “consist of” the various components and steps. Whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee.

What is claimed is:

1. An ultraviolet-light photodetector structure comprising:
a silicon-photoelectric conversion element;
a UV-to-visible down conversion layer having a halide-perovskite component that is a lead-free inorganic metal halide perovskite or a lead-free hybrid perovskite, wherein:
the halide-perovskite component has an absorption spectrum at wavelengths in the range of 400 nm or less and has an associate photoluminescence (PL) emission resulting in an emission spectrum with wavelengths in the range of above 400 nm, and
the UV-to-visible down conversion layer is associated with the silicon-photoelectric conversion element such that light in the absorption spectrum incident on the UV-to-visible down conversion layer results in a visible light emission which is incident on the silicon-photoelectric conversion element so as to produce an electrical signal.

2. The ultraviolet-light photodetector structure of claim 1, wherein the absorption. spectrum is at wavelengths in the range of from 10 nm to 400 nm and the emission spectrum is at wavelengths in the range of from above 400 nm to 1,100 nm.

3. The ultraviolet-light photodetector structure of claim 1, wherein the absorption spectrum is at wavelengths in the range of from 100 nm to 400 nm and the emission spectrum is at wavelengths in the range of from above 400 nm to 780 nm.

4. The ultraviolet-light photodetector structure of claim 1, wherein the halide-perovskite component is present in UV-to-visible down conversion layer in an amount from 0.1 wt % to 100 wt %.

5. The ultraviolet-light photodetector structure of claim 1, wherein the UV-to-visible down conversion layer is from about 1 μm to about 500 μm thick.

6. The ultraviolet-light photodetector structure of claim 1, wherein the halide-perovskite component is selected from the group consisting of CsCu₂I₃, CsCu₂Cl₃, CsCu₂Br₃, CsCu₂Cl_{3-x-y}Br_{y}Iₓ, Cs₃Cu₂I₅, Cs₃Cu₂Br₅, Cs₃Cu₂Br₅₋ₓIₓ, (C₅H₇N₂) ₂ZnBr₄, Rb₂CuBr₃, Rb₂CuCl₃, K₂CuCl₃, K₂CuBr₃, K₂CuI₃, K₂CuCl_{3-x-y}Br_{y}Iₓ; (TEP)₂Cu₂Br₄, (TEP)₂Cu₄Br₆, and mixtures thereof, wherein x is in the range of from 0 to 1, y is in the range of from 0 to 1, and TEP is tetraethylphosphonium (C₈H₂₀P).

7. The ultraviolet-light photodetector structure of claim 1, further comprising a filter layer configured to block at least a portion light at wavelengths of above 400 nm from reaching the UV-to-visible down conversion layer and to transmit at least a portion of light wavelengths at or below 400 nm to the UV-to-visible down conversion layer, and wherein the UV-to-visible down conversion layer is positioned between the silicon-photoelectric conversion element and the filter layer.

8. The ultraviolet-light photodetector structure of claim 1, wherein the UV-to-visible down conversion layer comprises the halide-perovskite component and an organic-host component.

9. The ultraviolet-light photodetector structure of claim 8, wherein the organic-host component and the halide-perovskite component have appropriate energy band alignment.

10. The ultraviolet-light photodetector structure of claim 9, wherein the organic-host is 1,3,5-tris(3-pyridyl-3-phenyl)benzene (TmPyPB).

11. The ultraviolet-light photodetector structure of claim 8, wherein the halide-perovskite component is present in an amount from 0.1 wt % to 99.9 wt % and the organic-host component is present in an amount from 0.1 wt % to 99.9 wt %, based on the total amount of the UV-to-visible down conversion layer.

12. The ultraviolet-light photodetector structure of clainx 11, where the halide-perovskite component is selected from the group consisting of CsCu₂I₃, CsCu₂Cl₃, CsCu₂Br₃, CsCu₂Cl_{3-x-y}Br_{y}Iₓ, Cs₃Cu₂I₅, Cs₃Cu₂Br₅, Cs₃Cu₂Br₅₋ₓIₓ, (C₅H₇N₂) ₂ZnBr₄, Rb₂CuBr₃, Rb₂CuCl₃, K₂CuCl₃, K₂CuBr₃, K₂CuI₃, K₂CuCl_{3-x-y}Br_{y}Iₓ; (TEP)₂Cu₂Br₄, (TEP)₂Cu₄Br₆, nd mixtures thereof, wherein x is in the range of from 0 to 1, y is in the range of from 0 to 1, and TEP is tetraethylphosphonium (C&H 20P).

13. The ultraviolet-light photodetector structure of claim 12, wherein the absorption spectrum is at wavelengths in the range of from 10 nm to 400 nm and the emission spectrum is in the range of from above 400 nm to 1,100 nm.

14. The ultraviolet-light photodetector structure of claim 13, wherein the UV-to-visible down conversion layer is from about 1 μm to about 500 μm thick.

15. The ultraviolet-light photodetector structure of claim 14, wherein the organic-host component and the halide-perovskite component have appropriate energy band alignment.

16. The ultraviolet-light photodetector structure of claim 15, further comprising a filter layer configured to block at least a portion light of wavelengths above 400 nm from reaching the UV-to-visible down conversion layer and to transmit at least a portion of light wavelengths at or below 400 nm to the UV-to-visible down conversion layer, and wherein the UV-to-visible down conversion layer is positioned between the silicon-photoelectric conversion element and the filter layer.

17. A method for detecting UV light, the method comprising:
exposing a UV-to-visible down conversion layer to light so as to generate an emission having a wavelength in an emission spectrum, wherein the UV-to-visible down conversion layer has a halide-perovskite component that is a lead-free inorganic metal halide perovskite or a lead-free hybrid perovskite, and the halide-perovskite component has an absorption spectrum at wavelengths of 400 nm or less, the emission is a photoluminescence (PL) emission associated with the absorption spectrum, and the emission spectrum is at wavelengths of above 400 nm, and
exposing a silicon-photoelectric conversion element to the emission so as to produce an electrical signal representative of the amount of an exposure spectrum of ultraviolet light in the light, the exposure spectrum of ultraviolet light being at wavelengths of 400 nm or less.

18. The method of claim 17, wherein the step of exposing a UVIto-visible down conversion layer to the light, further comprises:
filtering the light so as to reduce or remove light wavelengths above 400 nm; and
exposing the UV-to-visible down conversion layer to the filtered light.

19. A method for producing an ultraviolet-light photodetector structure, the method comprising:
providing a silicon-photoelectric conversion element;
depositing a halide-perovskite component and an organic host material onto the silicon-photoelectric conversion element by vacuum thermal evaporation film co-deposition to produce a UV-to-visible down conversion layer on the silicon-photoelectric conversion element, wherein the halide-perovskite component is a lead-free inorganic metal halide perovskite or a lead-free hybrid perovskite, has an absorption spectrum at a wavelengths in the range of 400 nm or less and has an associate photoluminescence (PL) emission resulting in an emission spectrum with wavelengths in the range of above 400 nm.

20. The method of claim 19, wherein the UV-to-visible down conversion layer is associated with the silicon-photoelectric conversion element such that ultraviolet light in the absorption spectrum incident on the UV-to-visible down conversion layer results in a visible light emission which is incident on the silicon-photoelectric conversion element so as to produce an electrical signal.

21. The method of claim 20, further comprising adding a filter layer, wherein the filter layer is configured to block at least a portion light of wavelengths above 400 nm from reaching the UV-to-visible down conversion layer and to transmit at least a portion of light wavelengths at or below 400 nm to the UV-to-visible down conversion layer, and wherein the UV-to-visible down conversion layer is positioned between the silicon-photoelectric conversion element and the filter layer.
